(19) United States
(12) Patent Application Publication
(10) Pub. No.: US 2022/0028897 A1
(43) Pub. Date: Jan. 27, 2022

(54) ELECTRONIC DEVICE WITH A FREQUENCY SIGNAL TRANSMITTED TO AT LEAST THREE NODES OF A SIGNAL LINE

(71) Applicant: InnoLux Corporation, Miao-Li County (TW)

(72) Inventors: Ming-Jou TAI, Miao-Li County (TW); Chia-Hao TSAI, Miao-Li County (TW); Yi-Shiuan CHERNG, Miao-Li County (TW); You-Cheng LU, Miao-Li County (TW)

(73) Assignee: InnoLux Corporation, Miao-Li County (TW)

(21) Appl. No.: 17/352,377

(22) Filed: Jun. 21, 2021

(30) Foreign Application Priority Data
Jul. 21, 2020 (CN) 202010703582.5

(51) Int. Cl. H01L 27/12; H01L 25/18

(52) U.S. Cl. CPC H01L 27/124; H01L 23/60; H01L 25/18

(57) ABSTRACT

An electronic device includes a driving circuit, an integrated circuit and a plurality of transmission lines. The driving circuit includes a plurality of transistors and a signal line. Each of the plurality of transistors has a control terminal to receive a frequency signal. The signal line is coupled to the control terminals of the transistors and includes a first node, a second node and a third node. The second node is located between the first node and the third node. The first node, the second node and the third node is used to receive the frequency signal. The integrated circuit is used to transmit the frequency signal. The plurality of transmission lines are coupled between the integrated circuit and the signal line. The integrated circuit transmits the frequency signal to the first node, the second node and the third node of the signal line through the plurality of transmission lines.

### CROSS REFERENCE TO RELATED APPLICATION

This non-provisional application claims priority to China patent application No.202010703582.5, filed 2020 Jul. 21, and incorporated herein by reference in its entirety.

### BACKGROUND OF THE DISCLOSURE

### 1. Field of the Disclosure

The disclosure is related to an electronic device, and more particularly, an electronic device where a frequency signal is provided to a plurality of transistors of a driving circuit by providing the frequency signal to at least three nodes of a signal line through a plurality of transmission lines.

### 2. Description of the Prior Art

As the resolution of display panels continues to increase, the number and complexity of components inside the circuit also increase. In the wiring design of the circuit, there are a large number of crossovers and the line width is gradually reduced, causing the load of resistance and inductance to increase, which is not conducive to the driving of the panel circuit, and the control signal is also prone to be distorted due to delay.

However, there is still a lack of proper solution in this field to improve the circuit driving capability, while supporting high resolution, and meeting the specifications of products such as virtual reality devices.

### SUMMARY OF THE DISCLOSURE

An embodiment provides an electronic device including a driving circuit, an integrated circuit and a plurality of transmission lines. The driving circuit includes a plurality of transistors and a signal line. The plurality of transistors are each used to receive a frequency signal. The signal line is coupled to each of the transistors and includes a first node, a second node and a third node, where the second node is located between the first node and the third node, and each of the first node, the second node and the third node is configured to receive the frequency signal. The integrated circuit is used to transmit the frequency signal. The plurality of transmission lines are coupled between the integrated circuit and the signal line. The integrated circuit transmits the frequency signal to the first node, the second node and the third node of the signal line through the plurality of transmission lines.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 illustrates that an electronic device is used according to an embodiment.

FIG. 2 illustrates that an electronic device is used according to another embodiment.

FIG. 2 illustrates that an electronic device is used according to another embodiment.

FIG. 4 illustrates a layout diagram including electronic device of FIG. 1

FIG. 5 is a partial cross-sectional view of FIG. 4 along the line 5-5′.

FIG. 6 illustrates an electronic device according to an embodiment.

### DETAILED DESCRIPTION

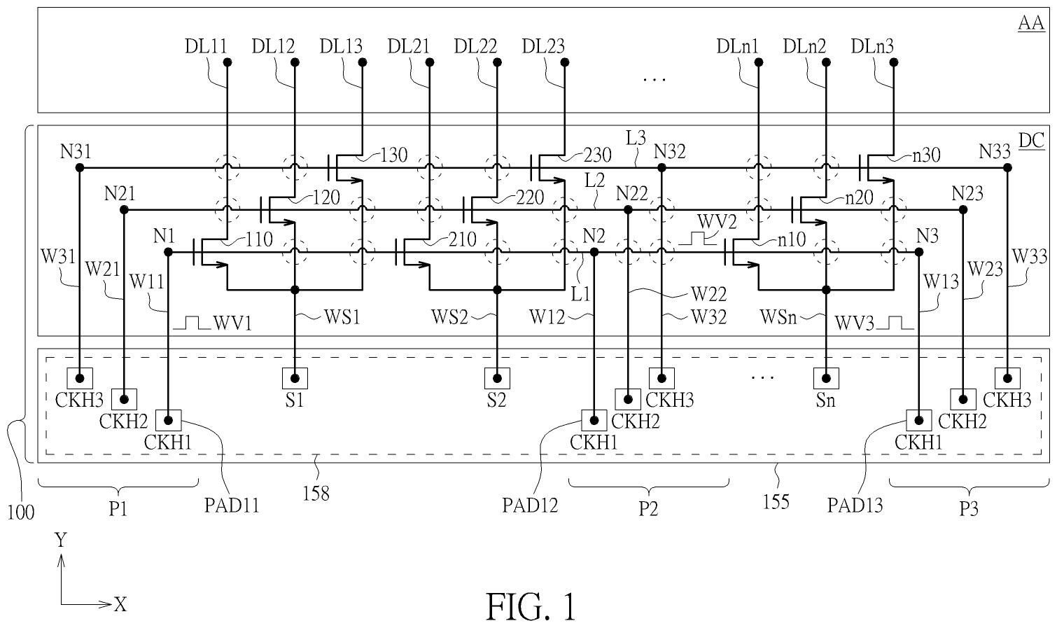

In order to improve the driving capability of the circuit, FIG. 1 to FIG. 6 are used to illustrate the solutions provided by the embodiments. The architecture, number of components, number of layers, positions, distributions, ratios and so on in FIG. 1 to FIG. 6 are only examples to help explain and understand the embodiments, but not to limit the types and scopes of the embodiments. If the ordinal numbers such as first and second are mentioned in the text, they are only used to distinguish different components, not to limit the order or importance of the manufacturing process.

Throughout the disclosure and the appended claims, certain words are used to refer to specific elements. Those skilled in the art should understand that electronic device manufacturers may refer to the same components by different names. This article does not intend to distinguish those elements with the same function but different names. In the following description and claims, words such as “have” and “include” are open-ended words, so they should be interpreted as meaning “including but not limited to”.

It should be understood that when an element or film layer is defined as being “on” or “connected to” another element or film layer, it can be directly on this another element or film layer or directly connected to the another element or layer; or it can be non-directly on this another element or film layer or non-directly connected to the another element or layer with another intervening element or film layer existing between the two element(s)/film layer(s). On the contrary, when an element is defined as being “directly on” or “directly connected to” another element or film layer, there is no intervening element or film layer between the two element(s)/film layer(s).

The term “approximate”, “equal”, “identical” or “substantially the same” usually means a range within 20% of a given value or range, or means a range within 10%, 5%, 3%, 2%, 1% or 0.5% of a given value or range.

In addition, the term “within the range from the first value to the second value” means that the range includes the first value, the second value, and other values in between.

Although terms such as first, second, third and so on can be used to describe different assembling elements, but these assembling elements are not limited by these terms. These terms are only used to distinguish an assembling element from another assembling element in the specification. In the claims, it is not limited to use the same terms, and the terms such as first, second, and third can be used to indicate the order of defining the elements. Therefore, in the following description, the first assembling element may be corresponding to the second assembling element in the claims.

It should be understood that the technical features of several different embodiments can be replaced, reorganized, and mixed to complete other embodiments without confliction or departing from the spirit of the disclosure.

FIG. 1 illustrates an example of using an electronic device 100 according to an embodiment. The electronic device 100 can include a driving circuit DC, signal lines DL11-DLn3, transmission lines W11-WSn, a bonding portion 158 and an integrated circuit (IC) 155.

As shown in FIG. 1, the driving circuit DC can be coupled to a display area AA through the signal line DL11, the signal line DL12, the signal line DL13, the signal line DL21, the signal line DL22, the signal line DL23, the signal line DLn1, the signal line DLn2 and the signal line DLn3.

The driving circuit DC can include a plurality of transistors and signal lines, such as the transistor 110, the transistor 120, the transistor 130, the transistor 210, the transistor 220, the transistor 230, the transistor n10, the transistor n20, the transistor n30, the signal line L1, the signal line L2 and the signal line L3. The signal line L1 can be coupled to the control terminals of the transistor 110, the transistor 210 and the transistor n10. The signal line L2 can be coupled to the control terminals of the transistor 120, the transistor 220 and the transistor n20. The signal line L3 can be coupled to the control terminals of the transistor 130, the transistor 230 and the transistor n30.

As shown in FIG. 1, the transistor 110, the transistor 120 and the transistor 130 can be of the 1^{st} group of transistors; the transistor 210, the transistor 220 and the transistor 230 can be of the 2^{nd} group of transistors; and the transistor n10, the transistor n20 and the transistor n30 can be of the n^{th} group of transistors. There can be more groups of transistors between the 2^{nd} group of transistors and the n^{th} group of transistors. Hence, in the example, n can be a positive integer, and n>2. In FIG. 1, each group of transistors includes three transistors, this is merely an example, and embodiments are not limited thereto.

As shown in FIG. 1, the signal source Si can provide signals to the transistor 110, the transistor 120 and the transistor 130 through the transmission line WS1. The signal source S2 can provide signals to the transistor 210, the transistor 220 and the transistor 230 through the transmission line WS2. The signal source Sn can provide signals to the transistor n10, the transistor n20 and the transistor n30 through the transmission line WSn.

The signal source S1, signal source S2 and signal source Sn can be located in the integrated circuit 155. The transmission line WS1, the transmission line WS2 and the transmission line WSn between the signal source S1, the signal source S2, the signal source Sn and the driving circuit DC can be connected and built by bonding.

As shown in FIG. 1, the first terminals of the transistor 110, the transistor 120 and the transistor 130 can be respectively coupled to the signal line DL11, the signal line DL12 and the signal line DL13. The first terminals of the transistor 210, the transistor 220 and the transistor 230 can be respectively coupled to the signal line DL21, the signal line DL22 and the signal line DL23. The first terminals of the transistor n10, the transistor n20 and the transistor n30 can be respectively coupled to the signal line DLn1, the signal line DLn2 and the signal line DLn3.

For example, the signal line DL11, the signal line DL12, the signal line DL13, the signal line DL21, the signal line DL22, the signal line DL23, the signal line DLn1, the signal line DLn2 and the signal line DLn3 can be used for providing signals to the display area AA of the display equipment.

The transistor 110 can receive the signals from the signal source S1 through the transmission line WS1 so as to transmit the signals to the display area AA for the display area AA to display accordingly.

Likewise, each of the transistor 120 and the transistor 130 can receive the signals from the signal source S1 through the transmission line WS1, and can transmit the signals to the display area AA through the signal line DL12 or the signal line DL13 for the display area AA to display accordingly.

Likewise, each of the transistor 210 to the transistor 230 can receive the signals from the signal source S1 through the transmission line WS2, and can transmit the signals to the display area AA through the signal line DL21, the signal line DL22 or the signal line DL23 for the display area AA to display accordingly.

Likewise, each of the transistor n10 to the transistor n30 can receive the signals from the signal source Sn through the transmission line WSn, and can transmit the signals to the display area AA through the signal line DLn1, the signal line DLn2 or the signal line DLn3 for the display area AA to display one pixel or a plurality of pixels accordingly.

As shown in FIG. 1, the control terminals of the transistor 110, the transistor 210 and the transistor n10 can receive the frequency signal CKH1 through the signal line L1. The control terminals of the transistor 120, the transistor 220 and the transistor n20 can receive the frequency signal CKH2 through the signal line L2. The control terminals of the transistor 130, the transistor 230 and the transistor n30 can receive the frequency signal CKH3 through the signal line L3.

Here the transistor 110, the transistor 210, the transistor n10, the signal line L1, the transmission line W11, the transmission line W12 and the transmission line W13 are taken as an example to explain an embodiment.

Each of the transistor 110, the transistor 210, the transistor n10 has a control terminal used to receive the frequency signal CKH1. The signal line L1 is coupled to the control terminals of each of the transistor 110, the transistor 210, the transistor n10. The signal line L1 has a first node N1, a second node N2 and a third node N3, where the second node N2 is located between the first node N1 and the third node N3. The first node N1, the second node N2 and the third node N3 are used to receive the frequency signal CKH1. The integrated circuit is used to transmit the frequency signal CKH1. The transmission line W11, the transmission line W12 and the transmission line W13 are coupled between the integrated circuit 155 and the signal line L1. The integrated circuit 155 can transmit the frequency signal CKH1 to the first node N1, the second node N2 and the third node N3 of the signal line L1 through the transmission line W11, the transmission line W12 and the transmission line W13.

According to embodiments, the driving circuit DC can be a demultiplexer or a gate driver. The first node N1, the second node N2 and the third node N3 of the signal line L1 can be respectively corresponding to the first portion P1, the second portion P2 and the third portion P3 of the bonding portion 158. The second portion P2 can be located between the first portion P1 and the third portion P3. In this embodiment, the first portion P1 can be formed using a plurality of pads PAD11 coupled to at least the first node N1. Likewise, the second portion P2 can be formed using a plurality of pads PAD12 coupled to at least the second node N2, and the third portion P3 can be formed using a plurality of pads PAD13 coupled to at least the third node N3. If the signal line L1 has a fourth node N4 (as shown in FIG. 3) due to actual product requirements, the bonding portion 158 can have a fourth portion P4 (as shown in FIG. 3) including a plurality of pads PAD14 (as shown in FIG. 3). In the embodiment, the number of pads in each portion of the bonding portion 158 is three, but embodiments are not limited thereto. As shown in FIG. 1, by transmitting the frequency signal CKH1 to the second N2, the waveform WV2 of the frequency signal CKH1 at the second portion P2 can be similar to the waveform WV1 of the frequency signal CKH1 at the first portion P1 and the waveform WV3 of the frequency signal CKH1 at the third portion P3, and therefore the frequency signal CKH1 can be prevented from being delayed and distorted.

Likewise, the first node N21, the second node N22 and the third node N23 can be respectively corresponding to the first portion P1, the second portion P2 and the third portion P3 and be used to receive the frequency signal CKH2 to prevent the frequency signal CKH2 from being delayed and distorted in the second portion P2.

Likewise, the first node N31, the second node N32 and the third node N33 can be respectively corresponding to the first portion P1, the second portion P2 and the third portion P3 and be used to receive the frequency signal CKH3 to prevent the frequency signal CKH3 from being delayed and distorted in the second portion P2.

Because the frequency signal CKH1, the frequency signal CKH2 and the frequency signal CKH3 can be prevented from being delayed and distorted in the second portion P2, the driving capability and the operation accuracy of the driving circuit DC are improved.

According to embodiments, the signal line L1 can be placed along the first reference axis X, the plurality of transmission lines (such as the transmission line W12, the transmission line W22 and the transmission line W32) can be placed along the second reference axis Y, and the second reference axis Y can be substantially perpendicular to the first reference axis X. The first reference axis X and the second reference axis Y can be defined from a top view when performing the place-and-route of the circuit.

According to embodiments, in the driving circuit DC, the plurality of transmission lines (such as the transmission line W11 to the transmission line W33 shown in FIG. 1) can be formed on a conductive layer, and the plurality of transistors (such as the transistor 110 to the transistor n30 shown in FIG. 1) can be formed on another conductive layer different from the conductive layer on which the transmission lines are formed.

As shown in FIG. 1, the integrated circuit 155 can include the bonding portion 158 used to perform wire bonding. Each of the plurality of transmission lines can be electrically connected to the integrated circuit 155 at a corresponding pad of the bonding portion 158.

For example, as shown in FIG. 1, the transmission line W11, the transmission line W12 and the transmission line W13 can be coupled to the integrated circuit 155 through the pad PAD11, the pad PAD12 and the pad PAD13 respectively by means of wire bonding. Likewise, the transmission line W21, the transmission line W22, the transmission line W23, the transmission line W31, the transmission line W32, the transmission line W33, the transmission line WS1, the transmission line WS2 and the transmission line WSn can be coupled to the bonding portion 158 of the integrated circuit 155 through the pads (shown as squares in FIG. 1) by means of wire bonding.

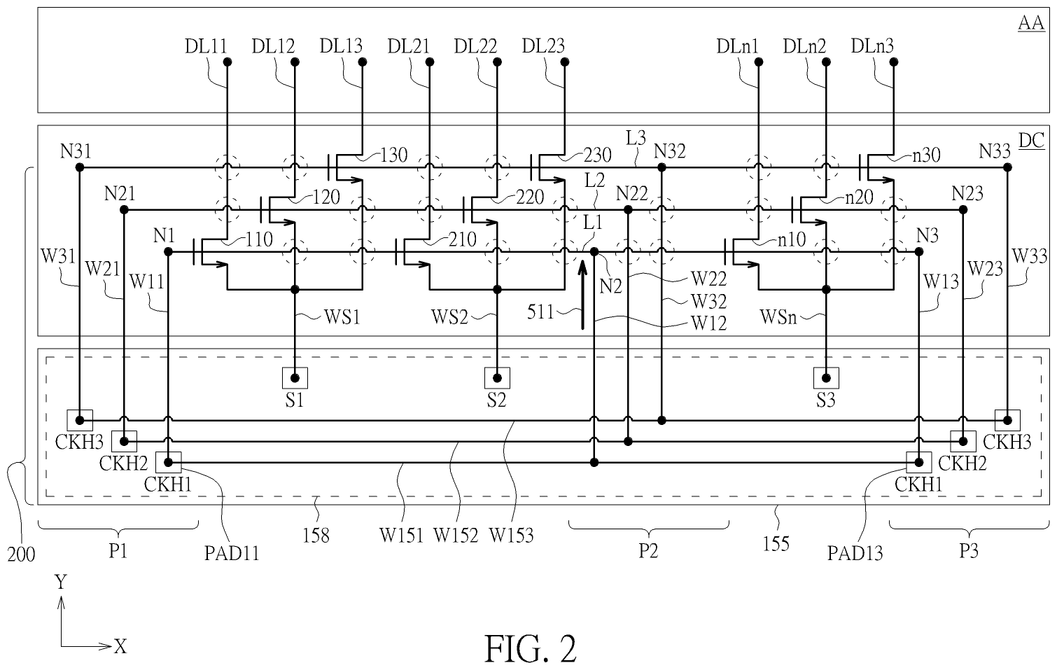

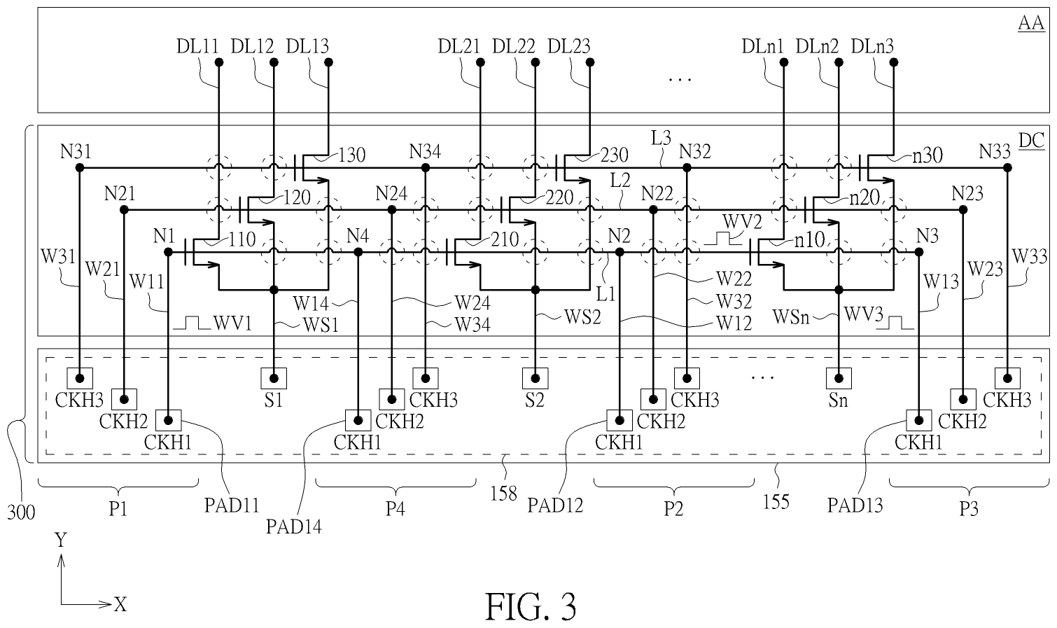

FIG. 2 illustrates an example of using an electronic device 200 according to another embodiment. If the number of the pads PAD11 and PAD13 is smaller than the number of the nodes N1 to N3 of the signal line L1, the structure of FIG. 2 can be used. As shown in FIG. 2, in the bonding portion 158, the conductive line W151 can be used to connect the pad PAD11 and the pad PAD13 of the integrated circuit 155 for transmitting the frequency signal CKH1. In the second portion P2, the transmission line W12 can be coupled to the conductive line W151 in the bonding portion 158 to transmit the frequency signal CKH1 to the second node N2. The similarities of FIG. 1 and FIG. 2 will not be repeated. According to another embodiment, another node between the second node N2 and the first node N1 or between the second node N2 and the third node N3 can be set, and the frequency signal CKH1 can be transmitted to the set node through another transmission line coupled to the conductive line W151.

In other words, the integrated circuit 155 can include the conductive line W151, and a plurality of transmission lines (such as the transmission line W11, the transmission line W12 and the transmission line W13) can be electrically connected to one another through the conductive line W151. In FIG. 2, the signal path 511 on the transmission line W12 will be described below.

Likewise, the integrated circuit 155 can further include the conductive line W152, and the transmission line W21, the transmission line W22 and the transmission line W23 can be electrically connected to one another through the conductive line W152 to transmit the frequency signal CKH2.

Likewise, the integrated circuit 155 can further include the conductive line W153, and the transmission line W31, the transmission line W32 and the transmission line W33 can be electrically connected to one another through the conductive line W152 to transmit the frequency signal CKH3.

In FIG. 2, the transmission line W12, the transmission line W22 and the transmission line W32 can be formed on a glass substrate.

By means of the structure of FIG. 2, when the number of the pads is smaller than the number of the nodes of the signal line, the transmission lines can be set to transmit the frequency signal to the driving circuit DC to improve the driving capability of the transistor.

According to embodiments, the transmission line W12, the transmission line W22 and the transmission line W32 can be disposed in an area of the bonding portion where the density of bonding is lower so as to decrease the loading to another circuit. The density of bonding can be defined by the number of transmission lines in the same unit area.

As shown in FIG. 1 and FIG. 2, the frequency signal can be transmitted in three portions (such as the first portion P1, the second portion P2 and the third portion P3) to the driving circuit DC to improve the driving capability. However, FIG. 1 and FIG. 2 are merely examples, and the number of portions of inputting signal can be increased as shown in FIG. 3.

FIG. 3 illustrates an example of using the electronic device 300 according to another embodiment. Compared with FIG. 1, the electronic device 300 of FIG. 3 further includes the transmission line W14, the transmission line W24 and the transmission line W34. The transmission line W14, the transmission line W24 and the transmission line W34 can be respectively coupled between the integrated circuit 155 and the signal line L1, between the integrated circuit 155 and the signal line L2, and between the integrated circuit 155 and the signal line L3. Hence, the frequency signal CKH1 can be transmitted to the fourth node N4 of the signal line L1, the frequency signal CKH2 can be transmitted to the fourth node N24 of the signal line L2, and the frequency signal CKH3 can be transmitted to the fourth node N34 of the signal line L3. The transmission line W14, the transmission line W24 and the transmission line W34 can be corresponding to the fourth portion P4.

Taking the signal line L1 as an example, compared with FIG. 1, the signal line L1 in FIG. 3 can further include the fourth node N4 located between the first node N1 and the second node N2, and the integrated circuit 155 can transmit the frequency signal CKH1 to the fourth node N4 through the transmission line W14.

FIG. 3 merely provides an example to describe that the frequency signal can be transmitted to the signal line of the driving circuit DC from four portions. According to embodiments, the frequency signal can be transmitted to the signal line of the driving circuit DC from four portions, five portion or even more portions to further avoid the distortion of the frequency signal and improve the driving capability.

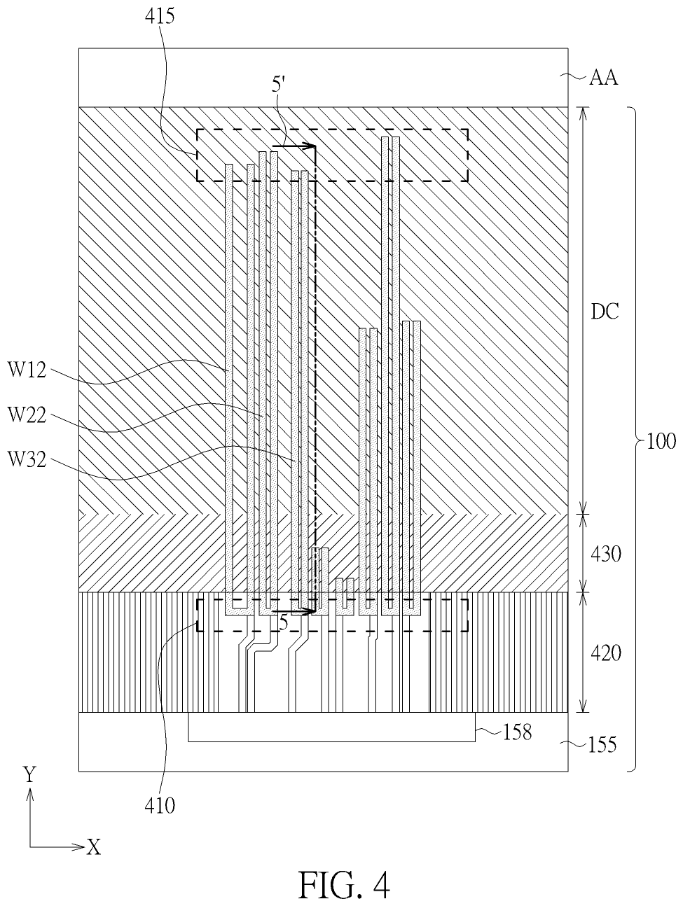

FIG. 4 illustrates a layout diagram including the driving circuit DC, the bonding portion 158 and the integrated circuit 155 shown in FIG. 1. FIG. 4 can be a top view of the layout. As shown in FIG. 4, the integrated circuit 155 on the substrate can be electrically connected to the driving circuit DC through the bonding portion 158 and through the transmission line W12, the transmission line W22 and the transmission line W32.

The electronic device can further include the electrostatic discharge region 430 located beside the driving circuit DC. Each of the transmission line W12, the transmission line W22 and the transmission line W32 can pass through the electrostatic discharge region 430 to be coupled between the integrated circuit 155 and the driving circuit DC. The electrostatic discharge region 430 can be set to avoid the accumulation of the electrical charges. Therefore, according to another embodiment, the transmission line W12, the transmission line W22 and the transmission line W32 can be coupled between the integrated circuit 155 and the driving circuit DC without passing through the electrostatic discharge region 430.

For the purpose of brevity, the bonding portion and the electrostatic discharge region 430 are omitted in FIG. 1, FIG. 2 and FIG. 3 and illustrated in FIG. 4.

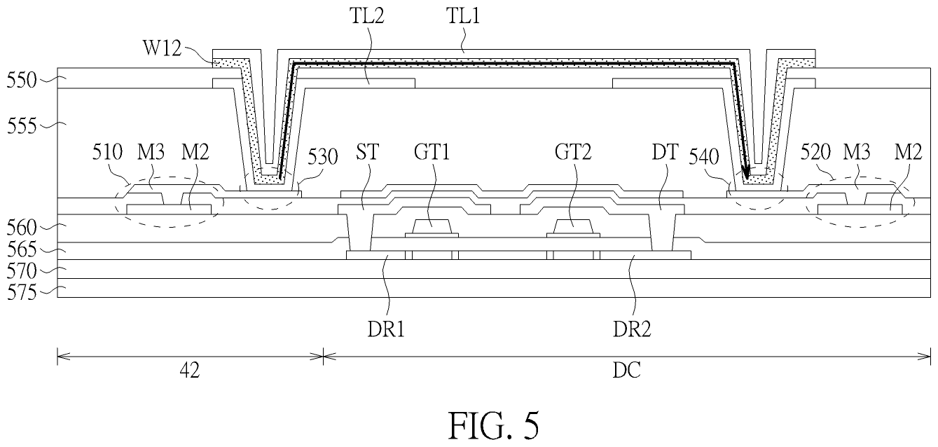

According to embodiments, the transmission line W12, the transmission line W22 and the transmission line W32 can be bridged by the conductive layer to transmit signals. Hereinafter, the transmission line W12 in FIG. 1 to FIG. 4 is taken as an example to describe the bridging of the conductive layer. The conductive layer M2 to the transmission line W12 mentioned below can be seen in FIG. 5.

FIG. 5 is a partial cross-sectional view of FIG. 4 along the line 5-5′. As shown in FIG. 5, the portion 510 and the portion 520 can be located in the bonding portion 42. In the portion 530, the signals can be transmitted from the conductive line M3 (e.g., the conductive line W151 in FIG. 2) to the transmission line W12, so the frequency signal CKH1 can be transmitted through the transmission line W12 to the conductive line M3 and the conductive line M2 (such as a pad) and be further transmitted to the transistor DR1 and the transistor DR2 of the driving circuit DC.

The transmission line W12 can be used to transfer each of the frequency signal CKH1 to the frequency signal CKH3. Since the transmission line W12 is only used for short-distance transferring, the thickness of the transmission line W12 can be smaller to reduce the manufacture risk of climbing. The transmission line W12 can be disposed under a planar layer to decrease the loading.

In FIG. 5, the frequency signal CKH1 is transferred from the conductive layer M3 to the transmission line W12 when being transmitted through the transmission line W12. However, this is merely an example, and embodiments are not limited thereto. According to embodiments, the signal on the transmission line W12 can be transferred from the conductive layer M2 to the conductive layer M3.

In the bonding portion 42 and the driving circuit DC, there can be the insulating layer 550, the planar layer 555, the dielectric layer 560, the gate dielectric layer 565, the buffer layer 570, the substrate 575, the source terminal ST, the drain terminal DT, the gate terminal GT1, the gate terminal GT2, the doped area DR1, the doped area DR2, the transparent thin film conductive layer TL1 and the transparent thin film conductive layer TL2. The buffer layer 570 is disposed on the substrate 575. The gate dielectric layer 565, the doped area DR1 and the doped area DR2 are disposed on the buffer layer 570. The dielectric layer 560 covers the gate dielectric layer 565 which covers the doped area DR1 and the doped area DR2. The source terminal ST and the drain terminal DT pass through the dielectric layer 560 and the gate dielectric layer 565 to be electrically connected to the doped area DR1 and the doped area DR2. The gate terminal GT1 and the gate terminal GT2 are disposed on the gate dielectric layer 565 to form the transistor 110 in FIG. 1. For example, the substrate can be copper foil or resin. The buffer layer 570 can be aluminum nitride or polyimide. The dielectric layer 560 can be silicon dioxide or silicon nitride. The gate dielectric layer 565 can be silicon dioxide. The transparent thin film conductive layer TL1 and the transparent thin film conductive layer TL2 can be indium tin oxide layers. FIG. 5 is merely an example to describe the embodiment, but embodiments are not limited thereto.

Taking FIG. 1 and FIG. 5 as an example, the conductive layer where the transmission line W12, the transmission line W22 and the transmission line W32 are located can be formed using a low reflective material such as low-reflection metal (e.g., molybdenum) to be used as a black matrix, and the aperture ratio variation caused by the assembling offset between the thin film transistor array and the color filter can be reduced. The conductive layer where the transmission line W12, the transmission line W22 and the transmission line W32 are located can be disposed below a part of the common electrode to be used as a black matrix. According to another embodiment, the conductive layer where the transmission line W12, the transmission line W22 and the transmission line W32 are located can be disposed below all of the common electrode to be used as a plurality of black matrices. According to embodiments, the conductive layer where the transmission line W12, the transmission line W22 and the transmission line W32 are located can be electrically connected to the transparent thin film conductive layer TL1 and the transparent thin film conductive layer TL2 to increase the electrical uniformity of the common electrode.

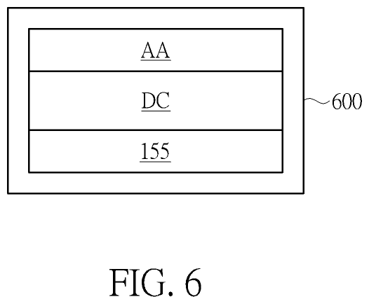

FIG. 6 illustrates an electronic device 600 according to an embodiment. The electronic device 600 can include the structure(s) shown in FIG. 1, FIG. 2, FIG. 3, FIG. 4 and/or FIG. 5. The electronic device 600 can include the display area AA, the driving circuit DC and the integrated circuit 155. The driving circuit DC can be the driving circuit DC shown in FIG. 1, FIG. 2, FIG. 3 and FIG. 4. According to embodiments, the device 600 can, for example, include (but is not limited to) a liquid crystal display, a light emitting diode display, a mini light emitting diode display, a micro light emitting diode display, an organic light emitting diode display, a quantum dot color filter display, a flexible display, and so on. The electronic device 600 can support a display with high pixel density (high pixels per inch) and/or high resolution. The electronic device 600 can meet the lower frame specifications and other specifications of the display of the virtual reality product.

In summary, in an electronic device, the frequency signal can be prevented from attenuation, distortion and waveform deterioration, and the operation accuracy can also be improved by transmitting the frequency signal to at least three nodes of the signal through a plurality of transmission lines and further providing the frequency signal to a plurality of transistors of the driving circuit. Therefore, the difficulties in the field can be overcome.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device comprising:
a driving circuit comprising:
a plurality of transistors each configured to receive a frequency signal; and
a signal line coupled to each of the transistors and comprising a first node, a second node and a third node, wherein the second node is located between the first node and the third node, and each of the first node, the second node and the third node is configured to receive the frequency signal;
an integrated circuit configured to transmit the frequency signal; and
a plurality of transmission lines coupled between the integrated circuit and the signal line, wherein the integrated circuit transmits the frequency signal to the first node, the second node and the third node of the signal line through the plurality of transmission lines.

2. The electronic device of claim 1, further comprising:
a bonding portion comprising a plurality of pads respectively disposed corresponding to the first node and the third node of the signal line;
wherein the transmission lines are electrically connected to the integrated circuit through the pads.

3. The electronic device of claim 2, wherein the plurality of pads are further disposed corresponding to the second node of the signal line.

4. The electronic device of claim 1, wherein the signal line is placed along a first reference axis, the plurality of transmission lines are placed along a second reference axis substantially perpendicular to the first reference axis.

5. The electronic device of claim 1, further comprising:
an electrostatic discharge region located between the driving circuit and the bonding portion;
wherein each of the plurality of transmission lines is coupled between the integrated circuit and the signal line through the bonding portion and the electrostatic discharge region.

6. The electronic device of claim 2, wherein the bonding portion further comprising a conductive line, and the transmission lines are electrically connected to one another through the conductive line in the bonding portion.

7. The electronic device of claim 1, wherein the transmission lines are generated using a low reflective material.
